(19) United States
(12) Patent Application Publication
(10) Pub. No.: US 2025/0280536 A1
(43) Pub. Date: Sep. 4, 2025

(54) ERASABLE PROGRAMMABLE NON-VOLATILE MEMORY CELL

(71) Applicant: eMemory Technology Inc., Hsin-Chu (TW)

(72) Inventors: Wein-Town SUN, Hsinchu County (TW); Hsueh-Wei CHEN, Hsinchu County (TW)

(21) Appl. No.: 19/055,961

(22) Filed: Feb. 18, 2025

Related U.S. Application Data
(60) Provisional application No. 63/559,234, filed on Feb. 29, 2024.

(51) Int. Cl. H10B 41/70; G11C 16/04; G11C 16/10; G11C 16/14; G11C 16/26; H10B 41/35

(52) U.S. Cl. CPC H10B 41/70; G11C 16/0441; G11C 16/10; G11C 16/14; G11C 16/26; H10B 41/35

(57) ABSTRACT

An erasable programmable non-volatile memory cell includes a well region, a first gate structure, a second gate structure, a first merged doped region, a second merged doped region and a third merged doped region. The first merged doped region is located beside a first side of the first gate structure. The second merged doped region is arranged between a second side of the first gate structure and a first side of the second gate structure. The third merged doped region is located beside a second side of the second gate structure. The first merged doped region, the first gate structure and the second merged doped region are collaboratively formed as a select transistor. The second merged doped region, the second gate structure and the third merged doped region are collaboratively formed as a floating gate transistor.

This application claims the benefit of U.S. provisional application Ser. No. 63/559,234, filed Feb. 29, 2024, the subject matters of which is incorporated herein by reference.

### FIELD OF THE INVENTION

The present invention relates to a non-volatile memory, and more particularly to an erasable programmable non-volatile memory cell.

### BACKGROUND OF THE INVENTION

As is well known, non-volatile memories (MVMs) have been widely used in a variety of electronic devices such as SD cards or solid state drives (SSDs). Generally, an erasable programmable non-volatile memory includes a memory array. The memory array includes a plurality of erasable programmable non-volatile memory cells.

For example, each erasable programmable non-volatile memory cell includes a floating gate transistor. The floating gate of the floating gate transistor can store hot carriers. The storage state of the floating gate transistor can be determined according to the amount of stored hot carriers. For example, the hot carriers are electrons or holes.

FIG. 1 is a schematic top view illustrating a conventional erasable programmable non-volatile memory cell. FIG. 2 is a schematic cross-sectional view illustrating the erasable programmable non-volatile memory cell shown in FIG. 1 and taken along the line AB. For example, the erasable programmable non-volatile memory cell is disclosed in U.S. Pat. No. 11,049,564 B2. For brevity, the erasable programmable non-volatile memory cell 450 is referred hereinafter to as a memory cell.

The memory cell 450 includes two serially-connected p-type transistors. These two p-type transistors are constructed in an N-well region NW. Three p-type doped regions 451, 452 and 453 are formed in the N-well region NW. In addition, two polysilicon gates 454 and 455 are formed over the areas between the three p-type doped regions 451, 452 and 453.

The first p-type transistor is used as a select transistor M_{S}. Moreover, the first p-type transistor includes a select gate, the p-type doped region 451 and the p-type doped region 452. The p-type doped region 451 is connected to a source line SL1.

The second p-type transistor is used as a floating gate transistor MF. Moreover, the second p-type transistor includes a floating gate, the p-type doped region 452 and the p-type doped region 453. The p-type doped region 453 is connected to a bit line BL1.

The floating gate 455 is extended externally to the top side of the n-type doped region 456 through the N-well region NW and the P-well region PW to cover the n-type doped region 456. Consequently, an erase gate region is defined. The n-type doped region 456 is connected to an erase line EL1. Optionally, a p-type block region PWBLK is formed between the P-well region PW and the n-type doped region 456.

As shown in FIG. 2, a gate dielectric layer 464 is located under the select gate 454 and contacted with the surface of the N-well region NW. Similarly, a gate dielectric layer 465 is located under the floating gate 455. In addition, the memory cell 450 is formed on a semiconductor substrate Sub. The periphery region of the memory cell 450 is surrounded by an isolation structure 401. The bottom side of the memory cell 450 is contacted with the semiconductor substrate Sub. For example, the N-well region NW, the P-well region PW and the p-type block region PWBLK are contacted with the semiconductor substrate Sub. In an embodiment, the isolation structure 401 is a shallow trench isolation (STI) structure.

By providing proper bias voltages to the source line SL1, the erase line EL1, the bit line BL1 and the select gate 454, a program action, an erase action or a read action is selectively performed on the memory cell 450. For example, when the program action is performed, the memory cell 450 receives a program voltage. Consequently, electrons are injected into the floating gate 455 from the channel region of the floating gate transistor MF. When the erase action is performed, the memory cell 450 receives an erase voltage. Consequently, electrons are ejected from the floating gate 455 to the n-type doped region 456 and exited from the floating gate transistor MF through the erase line EL1. The erase voltage is greater than the program voltage. For example, the erase voltage is approximately in the range between 14V and 19V, and the program voltage is approximately in the range between 7.5V and 9V.

Nowadays, by using the CMOS manufacturing process, IO devices capable of withstanding higher voltages and core devices capable of withstanding lower voltages can be formed on a single piece of semiconductor substrate. The core devices are also referred to as low voltage devices (or LV devices) such as LV P-type transistors and LV N-type transistors. The IO devices are also referred as medium voltage devices (or MV devices) such as MV P-type transistors and MV N-type transistors. Since the gate oxide layer of the LV device is thinner, the LV device is only able to withstand the lower voltage stress. However, the operation speed of the LV device is faster. The gate oxide layer of the MV device is thick enough to withstand the higher voltage stress. However, the operation speed of the MV device is slower.

Since the memory cell 450 needs to receive a high voltage, the select transistor M_{S} and the floating gate transistor M_{F} in the memory cell 450 are both MV devices. In addition, the memory cell 450 needs to comply with the design rules of the MV device. For example, the channel length Lg of the transistor of the MV device is at least 0.45 μm. In order to prevent the PN junction from being punched through, the dopant concentration of the P-well region PW is relatively low, and the length of the P-well region PW needs be at least 0.8 μm. That is, the length Lw of the isolation structure 401 overlying the P-well region PW needs to be at least greater than 0.8 μm, and the length the externally extended portion of the floating gate 455 is longer. For example, the channel length Lg is 0.55 μm, and the length Lw of the isolation structure 401 is 1.3 μm.

Due to the design rules of the MV device and the extended portion of the floating gate 455, the size of the conventional memory cell 450 is usually too large.

### SUMMARY OF THE INVENTION

An embodiment of the present invention provides an erasable programmable non-volatile memory cell. The erasable programmable non-volatile memory cell includes a first well region, a first gate structure, a second gate structure, a first spacer, a second spacer, a first merged doped region, a second merged doped region, a third merged doped region, a metal layer, a source line, a select gate line, a bit line, an assist line and a plate capacitor. The first well region is formed under a surface of the semiconductor substrate. The first gate structure and the second gate structure are formed on the first well region. The first spacer is formed on a sidewall of the first gate structure. The second spacer is formed on a sidewall of the second gate structure. The first merged doped region, the second merged doped region and the third merged doped region are formed under the surface of the first well region. The first merged doped region is located beside a first side of the first gate structure. The second merged doped region is arranged between a second side of the first gate structure and a first side of the second gate structure. The third merged doped region is located beside a second side of the second gate in structure. The metal layer is formed over the second gate structure. A vertical projection area of the metal layer covers the second gate structure. The source line is electrically connected with the first merged doped region. The select gate line is electrically connected with the first gate structure. The bit line is electrically connected with the third merged doped region. The assist line is connected with the metal layer. A first terminal of the plate capacitor is electrically connected with the metal layer. A second terminal of the plate capacitor is electrically connected with the second gate structure. The first merged doped region, the first gate structure and the second merged doped region are collaboratively formed as a select transistor. The second merged doped region, the second gate structure and the third merged doped region are collaboratively formed as a floating gate transistor.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic top view illustrating a conventional erasable programmable non-volatile memory cell;

FIG. 2 (prior art) is a schematic cross-sectional view illustrating the erasable programmable non-volatile memory cell shown in FIG. 1 and taken along the line AB;

FIGS. 3A to 3I schematically illustrate the steps of a method of manufacturing an erasable programmable non-volatile memory cell according to a first embodiment of the present invention;

FIG. 3J is a schematic equivalent circuit diagram of the erasable programmable non-volatile memory cell according to the first embodiment of the present invention;

FIG. 3K is a bias voltage table illustrating the bias voltages for performing a program action, an erase action and a read action on the memory cell according to the first embodiment of the present invention;

FIG. 3L is a schematic circuit diagram of performing the program action on the memory cell according to the first embodiment of the present invention;

FIG. 3M is a schematic circuit diagram of performing the erase action on the memory cell according to the first embodiment of the present invention;

FIG. 3N is a schematic circuit diagram of performing the erase action on the memory cell according to the first embodiment of the present invention;

FIG. 3O is a schematic circuit diagram of performing the read action on the memory cell according to the first embodiment of the present invention;

FIG. 4 is a schematic cross-sectional view illustrating the structure of a memory cell according to a second embodiment of the present invention;

FIG. 5 is a schematic cross-sectional view illustrating the structure of a memory cell according to a third embodiment of the present invention;

FIG. 6 is a schematic cross-sectional view illustrating the structure of a memory cell according to a fourth embodiment of the present invention;

FIG. 7 is a schematic cross-sectional view illustrating the structure of a memory cell according to a fourth embodiment of the present invention; and

FIG. 8 is a schematic cross-sectional view illustrating the structure of a memory cell according to a sixth embodiment of the present invention.

### DETAILED DESCRIPTION OF PREFERRED EMBODIMENTS

As mentioned above, in the CMOS manufacturing process, MV devices and LV devices are formed on a single piece of semiconductor substrate. The present invention provides an erasable programmable non-volatile memory cell. By using the manufacturing method including a medium voltage (MV) production procedure and a low voltage (LV) production procedure, the erasable programmable non-volatile memory cell is manufactured. That is, for designing the structure of the erasable programmable non-volatile memory cell of the present invention, a portion of the structure is manufactured according to the design rule of the MV device, and another portion of the structure is manufactured according to the design rule of the LV device. Consequently, the size of the erasable programmable non-volatile memory cell will be reduced, and the program voltage and the erase voltage provided to the memory cell will be decreased. For well understanding the concepts of the present invention, some embodiments of the memory cell will be described as follows.

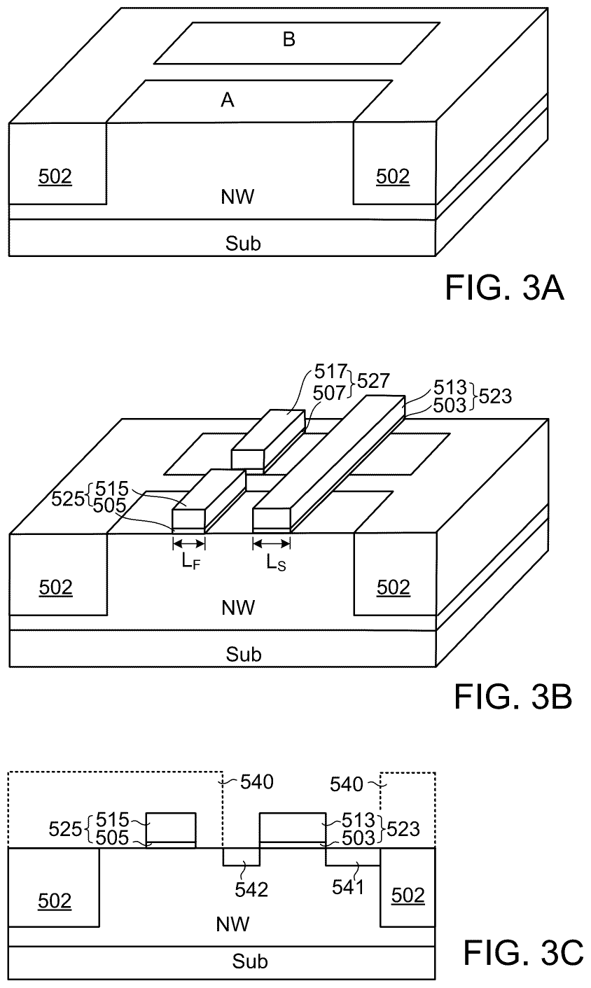

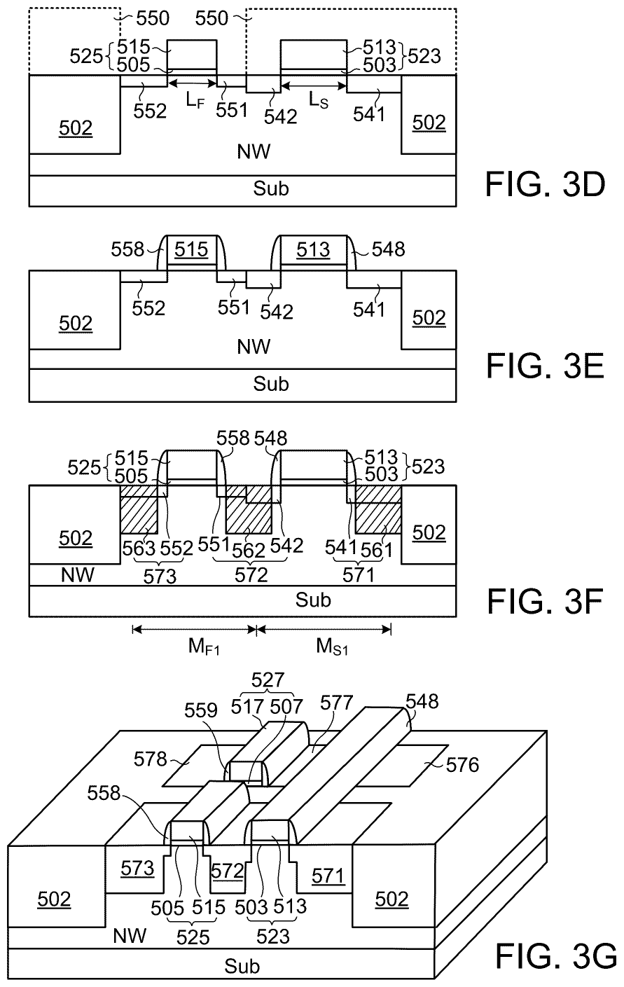

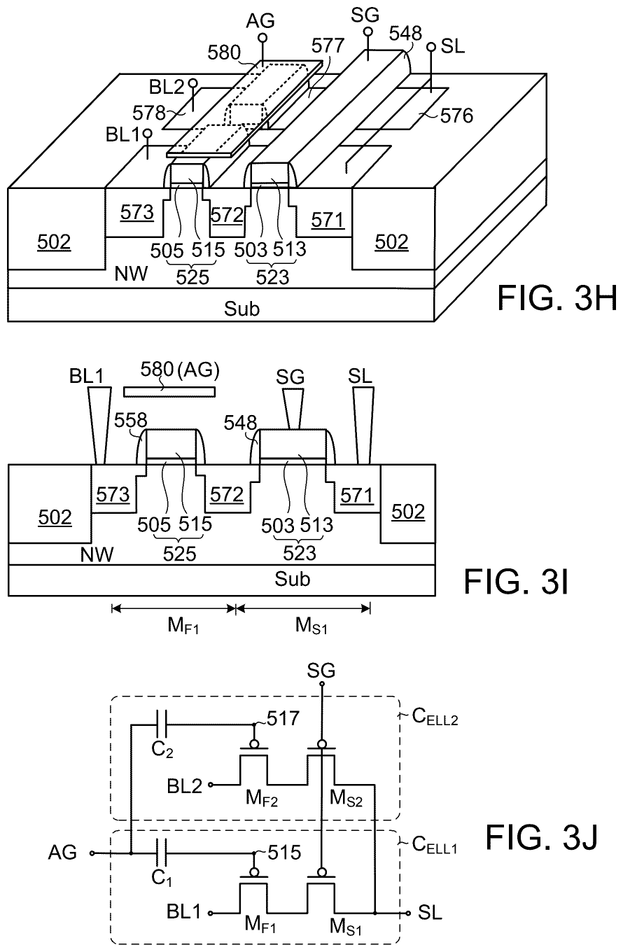

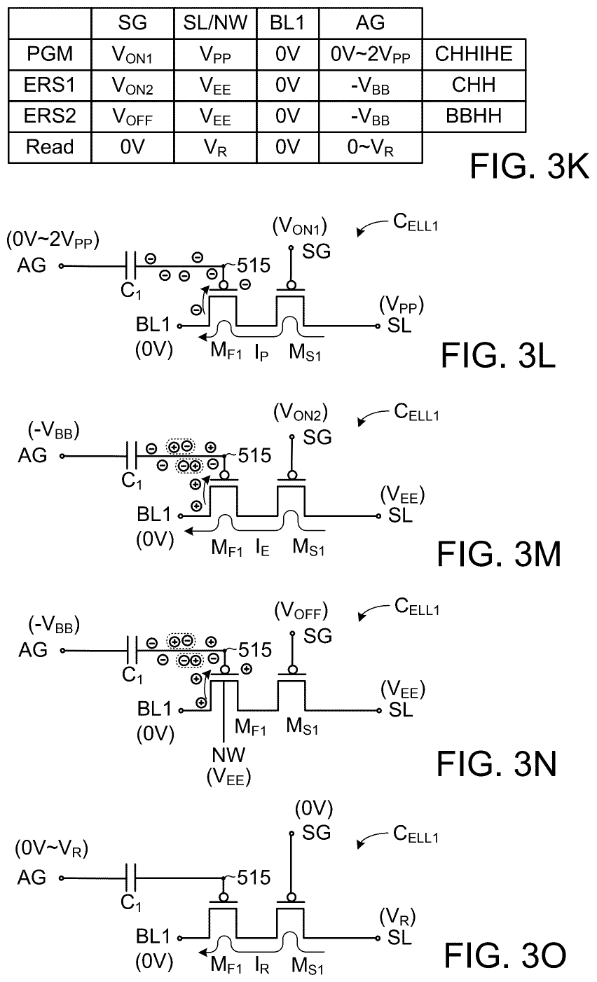

FIGS. 3A to 3I schematically illustrate the steps of a method of manufacturing an erasable programmable non-volatile memory cell according to a first embodiment of the present invention. FIG. 3J is a schematic equivalent circuit diagram of the erasable programmable non-volatile memory cell according to the first embodiment of the present invention. For brevity, the erasable programmable non-volatile memory cell is referred hereinafter to as a memory cell.

As shown in FIG. 3A, an isolation structure forming step is performed. An isolation structure 502 is formed on a semiconductor substrate Sub. Due to the isolation structure 502, a region A and a region B are defined. The semiconductor substrate Sub is covered by the isolation structure 502. The surface of the semiconductor substrate Sub corresponding to the region A and the region B is exposed. Then, a well region forming step is performed. A first well region (e.g., an N-well region) is formed under the surface of the semiconductor substrate Sub corresponding to the region A and the region B. In this embodiment, two memory cells are respectively constructed on the region A and the region B.

Then, a gate structure forming step is performed. As shown in FIG. 3B, three gate structures 523, 525 and 527 are formed on the surface of the N-well region. The gate structure 523 includes a gate dielectric layer 503 and a polysilicon gate layer 513. The gate structure 525 includes a gate dielectric layer 505 and a polysilicon gate layer 515. The gate structure 527 includes a gate dielectric layer 507 and a polysilicon gate layer 517. The gate dielectric layers 503, 505 and 507 are contacted with the N-well region. The polysilicon gate layer 513 is contacted with the gate dielectric layer 503. The polysilicon gate layer 515 is contacted with the gate dielectric layer 505. The polysilicon gate layer 517 is contacted with the gate dielectric layer 507.

The gate structure 525 is formed on the surface of the region A. The gate structure 527 is formed on the surface of the region B. The gate structure 525 and the gate structure 527 are not contacted with each other. The gate structure 523 is formed on the surface of the region A and externally extended to the region over the surface of the region B through the surface of the isolation structure 502. In addition, the region A is divided into three sub-regions by the two gate structures 525 and 523, and the region B is divided into three sub-regions by the two gate structures 527 and 523. That is, the gate structure 523 is shared by the two memory cells.

The polysilicon gate layer 515 of the gate structure 525 is served as the floating gate of a floating gate transistor. The polysilicon gate layer 517 of the gate structure 527 is served as the floating gate of another floating gate transistor. The polysilicon gate layer 513 of the gate structure 523 is served as select gates of two select transistors. That is, the two select gates of the two select transistors are connected to each other, but the floating gates of the two float gate transistors are not connected to each other.

In this embodiment, the channel length L_{F} of the floating gate transistor is smaller than the channel length L_{S} of the select transistor, i.e., L_{F}<L_{S}. For example, the channel length L_{S} of the select transistor is 0.55 μm, and the channel length L_{F} of the floating gate transistor is 0.35 μm.

Please refer to FIG. 3C. Then, the gate structure 525 and its two side areas in the region A are covered with a mask 540 shown in dotted lines, and the gate structure 523 and its two side areas are exposed. Similarly, the gate structure 527 and its two side areas in the region B are covered with the mask 540, and the gate structure 523 and its two side areas are exposed (not shown). For example, the mask 540 is a photoresist.

For example, in the region A, only a part of the surface between the gate structure 523 and the gate structure 525 is covered by the mask 540, and the other part of the surface between the gate structure 523 and the gate structure 525 is not covered by the mask 540. Then, a lightly doped drain process (LDD process) in the MV production procedure is performed. Consequently, p-type lightly doped drain regions (p-LDD regions) 541 and 542 are formed under the surface of the semiconductor substrate Sub uncovered by the mask 540. The p-LDD regions 541 and 542 are formed under the surface of the region A and respectively located beside the two sides of the gate structure 523. The doping concentrations of the p-LDD regions 541 and 542 are equal, and the doping depths of the p-LDD regions 541 and 542 are equal.

Please refer to FIG. 3D. After the mask 540 is removed, the gate structure 523 (and its side areas) in the region A and the region B are covered with a mask 550 shown in dotted lines. In other words, the region previously covered by mask 540 is exposed. For example, the mask 550 is a photoresist. Then, an LDD process in the LV production procedure is performed. Consequently, p-type lightly doped drain regions (p-LDD regions) 551 and 552 are formed under the surface of the semiconductor substrate Sub uncovered by the mask 550. The p-LDD regions 551 and 552 are formed under the surface of the region A and respectively located beside the two sides of the gate structure 525. The doping concentrations of the p-LDD regions 551 and 552 are equal, and the doping depths of the p-LDD regions 551 and 552 are equal.

The distance between the p-type lightly doped drain region 541 and the p-type lightly doped drain region 542 is Ls, which is used as a channel for the select transistor. The distance between the p-type lightly doped drain region 551 and the p-type lightly doped drain region 552 is L_{F}, which is used as a channel for the floating gate transistor. In this embodiment, the channel length L_{F} of the floating gate transistor is smaller than the channel length L_{S} of the select transistor, i.e., L_{F}<L_{S}.

The first LDD process belongs to the MV production procedure. The second LDD process belongs to the LV production procedure. In other words, the doping concentrations of the p-LDD regions 541 and 542 are less than the doping concentrations of the p-LDD regions 551 and 552, and the doping depth of the p-LDD regions 541 and 542 is deeper than the doping depth of the p-LDD regions 551 and 552.

Please refer to FIG. 3E. After the mask 550 is removed, a spacer 548 is formed on the sidewall of the gate structure 523, and a spacer 558 is formed on the sidewall of the gate structure 525. The spacer 548 is contacted with the sidewall of the gate structure 523. The spacer 558 is contacted with the sidewall of the gate structure 525.

Please refer to FIG. 3F. Then, a p-type ion implantation process is performed on the surface of the semiconductor substrate Sub by using the two gate structures 523 and 525 and the two spacers 548 and 558 as masks. Consequently, three p-type ion implantation regions 561, 562 and 563 shown in oblique lines are formed on three sub-regions of the region A uncovered by the two gate structures 523 and 525 and the two spacers 548 and 558. Especially, the p-type ion implantation regions 561, 562 and 563 have the highest doping concentration, and their dopant concentration is greater than the dopant concentration of the p-LDD regions 541, 542, 551 and 552.

Please refer to FIG. 3F again. Then, the p-LDD region 541 and the p-type ion implantation regions 561 are collaboratively formed as a merged p-doped region 571. The merged p-doped region 571 is formed under the surface of the semiconductor substrate Sub and located beside a first side of the gate structure 523. The p-LDD region 542, the p-LDD region 551 and the p-type ion implantation regions 562 are collaboratively formed as a merged p-doped region 572. The merged p-doped region 572 is formed under the surface of the semiconductor substrate Sub and arranged between the second side of the gate structure 523 and the first side of the gate structure 525. The p-LDD region 552 and the p-type ion implantation regions 563 are collaboratively formed as a merged p-doped region 573. The merged p-doped region 573 is formed under the surface of the semiconductor substrate Sub and located beside the second side of the gate structure 525. The p-LDD region 541 is located under the spacer 548 beside the first side of the gate structure 523. The p-LDD region 542 is located under the spacer 548 beside the second side of the gate structure 523. The p-LDD region 551 is located under the spacer 558 beside the first side of the gate structure 525. The p-LDD region 552 is located under the spacer 558 beside the second side of the gate structure 525.

In the region A, the gate structure 523 and the merged p-doped regions 571 and 572 on its two sides are collaboratively formed as a select transistor M_{S1}. In addition, the gate structure 525 and the two merged p-doped regions 572 and 573 on its two sides are collaboratively formed as a floating gate transistor M _{F1}. In this embodiment, the floating gate transistor M_{F1} and the select transistor M_{S1} are p-type transistors and constructed in the N-well region NW. That is, the body terminal of the floating gate transistor M_{F1} and the body terminal of the select transistor M_{S1} are connected to the N-well region NW.

The perspective view of the structure of FIG. 3F is shown in FIG. 3G. In the region B, the spacer 559 is formed on the sidewall of the gate structure 527. A merged p-doped region 576 is formed under the surface of the semiconductor substrate Sub and located beside the first side of the gate structure 523. A merged p-doped region 577 is formed under the surface of the semiconductor substrate Sub and arranged between the second side of the gate structure 523 and the first side of the gate structure 527. A merged p-doped region 578 is formed under the surface of the semiconductor substrate Sub and located beside the second side of the gate structure 527. Similarly, a floating gate transistor and a select transistor are constructed in the region B.

Please refer to FIG. 3H. Then, a metal layer 580 is formed over the polysilicon gate layers 515 and 517. The size of the metal layer 580 is greater than or equal to the size of the polysilicon gate layers 515 and 517. Consequently, the vertical projection area of the metal layer 580 completely covers the polysilicon gate layer 515 of the gate structure 525 and the polysilicon gate layer 517 of the gate structure 527. In some embodiments, the size of the metal layer 580 is smaller than the size of the polysilicon gate layers 515 and 517, and the vertical projection area of the metal layer 580 partially covers the polysilicon gate layer 515 of the gate structure 525 and the polysilicon gate layer 517 of the gate structure 527. The polysilicon gate layer 515 and the metal layer 580 are collaboratively formed as a first metal/poly plate capacitor. The polysilicon gate layer 517 and the metal layer 580 are collaboratively formed as a second metal/poly plate capacitor. After a step of forming metal conductor lines is completed, the two memory cells are fabricated. The cross-sectional view of the structure of FIG. 3H is shown in FIG. 3I.

Please refer to FIG. 3H and FIG. 3I. The merged p-doped region 571 is connected to a source line SL. The merged p-doped region 573 is connected to a bit line BL1. The polysilicon gate layer 513 is connected to a select gate line SG. The metal layer 580 is connected to an assist line AG. The merged p-doped region 576 is connected to the source line SL. The merged p-doped region 578 is connected to another bit line BL2.

As shown in FIG. 3J, the memory cell C_{ELL1} includes a select transistor M_{S1}, a floating gate transistor M_{F1} and a plate capacitor C₁. The gate terminal of the select transistor M_{S1} is connected to the select gate line SG. The first drain/source terminal of the select transistor M_{S1} is connected to the source line SL. The first drain/source terminal of the floating gate transistor M_{F1} is connected to the second drain/source terminal of the select transistor M_{S1}. The second drain/source terminal of the floating gate transistor M_{F1} is connected to the bit line BL₁. The first terminal of the plate capacitor C₁ is connected to the floating gate 515 of the floating gate transistor M_{F1}. The second terminal of the plate capacitor C₁ is connected to the auxiliary line AG. Similarly, the memory cell C_{ELL2} includes a select transistor M_{S2}, a floating gate transistor M_{F2} and a plate capacitor C₂. The gate terminal of the select transistor M_{S2} is connected to the select gate line SG. The first drain/source terminal of the select transistor M_{S2} is connected to the source line SL. The first drain/source terminal of the floating gate transistor M_{F2} is connected to the second drain/source terminal of the select transistor M_{S2}. The second drain/source terminal of the floating gate transistor M_{F2} is connected to the bit line B_{L2}. The first terminal of the plate capacitor C₂ is connected to the floating gate 517 of the floating gate transistor M_{F2}. The second terminal of the plate capacitor C₂ is connected to the auxiliary line AG. For example, the plate capacitors C₁ and C₂ are metal/poly plate capacitors.

As mentioned above, the memory cell C_{ELL1} of the first embodiment includes two transistors M_{F1} and M_{S1} and a plate capacitor C₁. Consequently, the memory cell C_{ELL1} may be referred to as a 2T1C memory cell. The plate capacitor C₁ is used as a coupling capacitor. When the erase action is performed, no hot carriers can be transferred through the coupling capacitor.

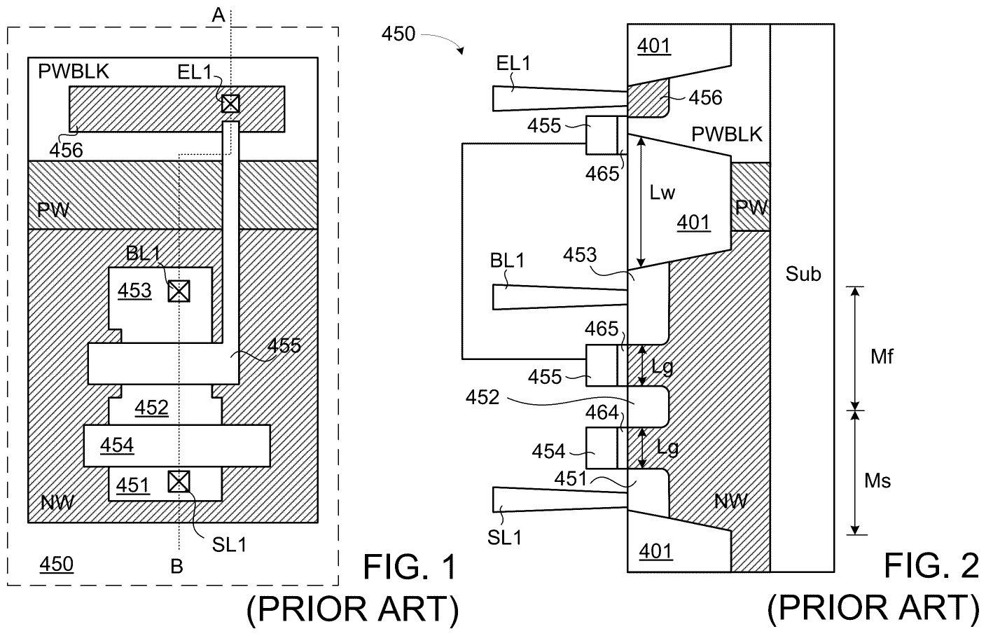

When compared with the memory cell of FIG. 1, the floating gate 515 in the memory cell of FIG. 3H is not extended to other areas, and the channel length LF of the floating gate transistor M_{F1} is shorter. Consequently, the size of the memory cell of the present invention can be greatly reduced by about 50% or more. Furthermore, electrons are injected from the channel of the floating gate transistor Mf to the floating gate when the conventional memory cell of FIG. 1 is subjected to the program action, and electrons are ejected to the erase line EL1 from the floating gate when the conventional memory cell of FIG. 1 is subjected to the erase action. However, the memory cell of the present invention is not equipped with the erase line. That is, the memory cell of the present invention does not have the carrier ejection path of the conventional memory cell. Consequently, by providing various bias voltages to the memory cell of the present invention, the program action, the erase action or the read action can be selectively performed.

FIG. 3K is a bias voltage table illustrating the bias voltages for performing a program action, an erase action and a read action on the memory cell according to the first embodiment of the present invention. FIG. 3L is a schematic circuit diagram of performing the program action on the memory cell according to the first embodiment of the present invention. FIG. 3M is a schematic circuit diagram of performing the erase action on the memory cell according to the first embodiment of the present invention. FIG. 3O is a schematic circuit diagram of performing the read action on the memory cell according to the first embodiment of the present invention. In FIG. 3K, two sets of bias voltages for erase action are provided according to different effects. Furthermore, the N-well region NW and the source line SL receive the same bias voltage.

Please refer to FIG. 3K and FIG. 3L. When the program action is performed, the source line SL receives a program voltage V_{PP}, the select gate line SG receives a first on voltage V_{ON1}, the bit line BL1 receives a ground voltage (0V), and the assist line AG receives a voltage between the ground voltage (0V) and twice the program voltage (i.e., 2×V_{PP}). The program voltage V_{PP} is in the range between 6V and 7.5V. The first on voltage V_{ON1} is between the ground voltage (0V) and ¾×V_{PP}. Obviously, the program voltage V_{PP} for the memory cell of the first embodiment is smaller than the program voltage V_{PP} for the conventional memory cell.

When the program action is performed, the select transistor M_{S1} is turned on, and a program current I_{P} is generated between the source line SL and the bit line BL1 When the hot carriers (e.g., holes) of the program current I_{P} flow through the pinch off point of the channel region of the floating gate transistor MF₁, a channel hot hole induced hot electron injection effect (also referred as a CHHIHE effect) is generated. Meanwhile, in the floating gate transistor M_{F1}, electron-hole pairs are generated at the junction between the merged p-doped region 573 and the N-well region NW. Since generated electrons are attracted by the voltage from the assist line AG, electrons are injected into the floating gate 515. The pinch off point is included in the channel region of the floating gate transistor M_{F1} and near the merged p-doped region 573 beside the bit line BL1.

Due to the differences between the merged p-doped regions 571, 572 and 573 in the memory cell C_{ELL1}, the program voltage V_{PP} can be reduced, and the programming efficiency can be enhanced. In the floating gate transistor M_{F1} of the memory cell of FIG. 3F, the p-LDD regions 551 and 552 near the two sides of the floating gate 515 have higher doping concentrations and smaller depths. Furthermore, the floating gate transistor M_{F1} has the shorter channel region. Consequently, when the program is performed on the memory cell C_{ELL1}, the provision of the lower program voltage V_{PP} can generate a higher electric field at the pinch off point of the channel region to increase the programming efficiency. Furthermore, in response to the lower program voltage V_{PP}, program current I_{P} is lower.

Please refer to FIG. 3K and FIG. 3M. When the erase action is performed, the source line SL receives an erase voltage V_{EE}, the select gate line SG receives a second on voltage V_{ON2}, and the bit line BL1 receives the ground voltage (0V). The assist line AG receives a voltage between the negative assist line voltage −V_{BB} and the ground voltage (0V). The negative assist line voltage −V_{BB} is lower than or equal to 0V. For example, the negative assist line voltage −V_{BB} is −5V, the erase voltage V_{EE} is in the range between 7V and 8V. The second on voltage V_{ON2} is in the range between the ground voltage (0V) and a voltage difference (V_{EE}−V_{T}), wherein V_{T} is threshold voltage of the select transistor M_{S1}. Obviously, the erase voltage V_{EE} provided to the memory cell of the first embodiment is lower than the erase voltage provided to the conventional memory cell.

When the erase action is performed, the select transistor M_{S1} is turned on, and an erase current I_{E} is generated between the source line SL and the bit line BL1. When the hot carriers (e.g., holes) of the erase current I_{E} flow through the pinch off point of the channel region of the floating gate transistor MF1, a channel hot hole injection effect (also referred as a CHH effect) is generated. Meanwhile, in the floating gate transistor M_{F1}, electron-hole pairs are generated at the junction between the merged p-doped region 573 and the N-well region NW. Since holes are attracted by the voltage from the assist line AG, holes are injected into the floating gate 515. After electron-hole combination in the floating gate 515, the erase action is completed.

Please refer to FIG. 3K and FIG. 3N. When the erase action is performed, the source line SL receives the erase voltage V_{EE}, the N-well region NW receives the erase voltage V_{EE}, the select gate line SG receives an off voltage V_{OFF}, and the bit line BL1 receives the ground voltage (0V). The assist line AG receives a voltage between the negative assist line voltage −V_{BB} and the ground voltage (0V). The negative assist line voltage −V_{BB} is lower than or equal to 0V. For example, the negative assist line voltage −V_{BB} is −5V.

When the erase action is performed, the select transistor M_{S1} is turned off, and no erase current is generated between the source line SL and the bit line BL1. Meanwhile, in the floating gate transistor M_{F1}, electron-hole pairs are generated at the junction between the merged p-doped region 573 and the N-well region NW. Consequently, a band-to-band hot hole injection effect (also referred as a BBHH effect) is generated. Since holes are attracted by the voltage from the assist line AG, holes are injected into the floating gate 515. After electron-hole combination in the floating gate 515, the erase action is completed.

Similarly, due to the differences between the merged p-doped regions 571, 572 and 573 in the memory cell C_{ELL1} and the short channel of the floating gate transistor M_{F1}, the provision of the lower erase voltage V_{EE} can complete the erase action.

Please refer to FIG. 3K and FIG. 3O. When the read action is performed, the source line SL receives a read voltage V_{R}, the select gate line SG receives the ground voltage (0V), the bit line BL1 receives the ground voltage (0V), and the assist line AG receives a voltage between the ground voltage (0V) and the read voltage V_{R}. For example, the read voltage V_{R} is 2.5V. The erase voltage V_{EE} is higher than the program voltage V_{PP}. The program voltage V_{PP} is higher than the read voltage V_{R}. The read voltage V_{R} is higher than the ground voltage (0V).

When the read action is performed, the select transistor M_{S1} is turned on, and a read current I_{R} is generated between the source line SL and the bit line BL1. The storage state of the memory cell can be determined according to the magnitude of the read current I_{R}. For example, in case that no electrons are stored in the floating gate 515, the magnitude of the read current I_{R} is very low (e.g., nearly zero). Consequently, it is determined that the memory cell is in an erased state. Whereas, in case that electrons are stored in the floating gate 515, the magnitude of the read current I_{R} is very high. Under this circumstance, it is determined that the memory cell is in a programmed state.

It is noted that structure of the memory cell of the first embodiment may be modified. For example, the structure of the coupling capacitor is modified to increase the voltage coupling ratio.

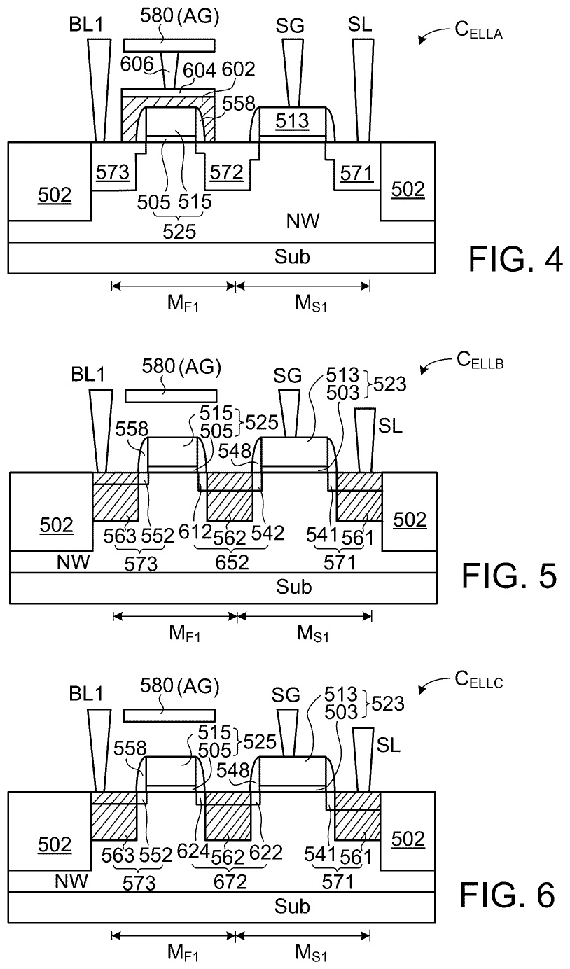

FIG. 4 is a schematic cross-sectional view illustrating the structure of a memory cell according to a second embodiment of the present invention. In comparison with the memory cell C_{ELL1} of the first embodiment, the memory cell C_{ELLA} of this embodiment further includes a block layer 602, a polysilicon layer 604 and a conducting line 606. For brevity, only the difference between the two memory cells C_{ELL1} and C_{ELLA} will be described as follows.

Please refer to FIG. 4. In the memory cell C_{ELLA}, the gate structure 525 and the spacer 558 are covered by the block layer 602. For example, the block layer 602 is a salicide block layer (SAB). The polysilicon layer 604 is formed on the top surface of the block layer 602. In addition, the conducting line 606 is arranged between the metal layer 580 and the polysilicon layer 604, and the conducting line 606 is electrically connected with the metal layer 580 and the polysilicon layer 604. Consequently, the polysilicon layer 604 and the polysilicon gate layer (i.e., the floating gate) 515 are collaboratively formed as a polysilicon/polysilicon plate capacitor. Since the distance between the two polysilicon layers 604 and 515 is shorter, the voltage coupling ratio of the coupling capacitor can be effectively enhanced.

In some other embodiments, the structures of the merged p-doped regions 571, 572 and 573 in the memory cell of the first embodiment are modified.

FIG. 5 is a schematic cross-sectional view illustrating the structure of a memory cell according to a third embodiment of the present invention. In comparison with the memory cell C_{ELL1} of the first embodiment, the structures of the merged p-doped regions 571, 652 and 573 are distinguished. For brevity, only the difference between the two memory cells C_{ELL1} and C_{ELLB} will be described as follows.

As shown in FIG. 5, the p-LDD region 541 and the p-type ion implantation regions 561 are collaboratively formed as the merged p-doped region 571. The merged p-doped region 571 is formed under the surface of the semiconductor substrate Sub and located beside a first side of the gate structure 523. The p-LDD region 542, a p-LDD region 612 and the p-type ion implantation regions 562 are collaboratively formed as the merged p-doped region 652. The merged p-doped region 652 is formed under the surface of the semiconductor substrate Sub and arranged between the second side of the gate structure 523 and the first side of the gate structure 525. The p-LDD region 552 and the p-type ion implantation regions 563 are collaboratively formed as a merged p-doped region 573. The merged p-doped region 573 is formed under the surface of the semiconductor substrate Sub and located beside the second side of the gate structure 525.

In this embodiment, the p-LDD regions 552 is formed by using the LDD process of the LV production procedure, and the p-LDD regions 541, 542 and 612 are formed by using the LDD process of the MV production procedure. Consequently, the doping concentrations of the p-LDD regions 541, 542 and 612 are equal, and the doping concentration of the p-LDD region 552 is greater than the doping concentration of the p-LDD region 541. The doping depths of the p-LDD regions 541, 542 and 612 are equal. The doping depth of the p-LDD region 541 is deeper than the doping depth of the p-LDD region 552.

FIG. 6 is a schematic cross-sectional view illustrating the structure of a memory cell according to a fourth embodiment of the present invention. In comparison with the memory cell C_{ELL1} of the first embodiment, the structures of the merged p-doped regions 571, 672 and 573 are distinguished. For brevity, only the difference between the two memory cells C_{ELL1} and C_{ELLC} will be described as follows.

As shown in FIG. 6, the p-LDD region 541 and the p-type ion implantation regions 561 are collaboratively formed as the merged p-doped region 571. The merged p-doped region 571 is formed under the surface of the semiconductor substrate Sub and located beside a first side of the gate structure 523. A p-LDD region 622, a p-LDD region 624 and the p-type ion implantation regions 562 are collaboratively formed as the merged p-doped region 672. The merged p-doped region 672 is formed under the surface of the semiconductor substrate Sub and arranged between the second side of the gate structure 523 and the first side of the gate structure 525. The p-LDD region 552 and the p-type ion implantation regions 563 are collaboratively formed as a merged p-doped region 573. The merged p-doped region 573 is formed under the surface of the semiconductor substrate Sub and located beside the second side of the gate structure 525.

In this embodiment, the p-LDD regions 541 is formed by using the LDD process of the MV production procedure, and the p-LDD regions 622, 624 and 552 are formed by using the LDD process of the LV production procedure. Consequently, the doping concentrations of the p-LDD regions 622, 624 and 552 are equal, and the doping concentration of the p-LDD region 552 is greater than the doping concentration of the p-LDD region 541. The doping depths of the p-LDD regions 622, 624 and 552 are equal. The doping depth of the p-LDD region 541 is deeper than the doping depth of the p-LDD region 552.

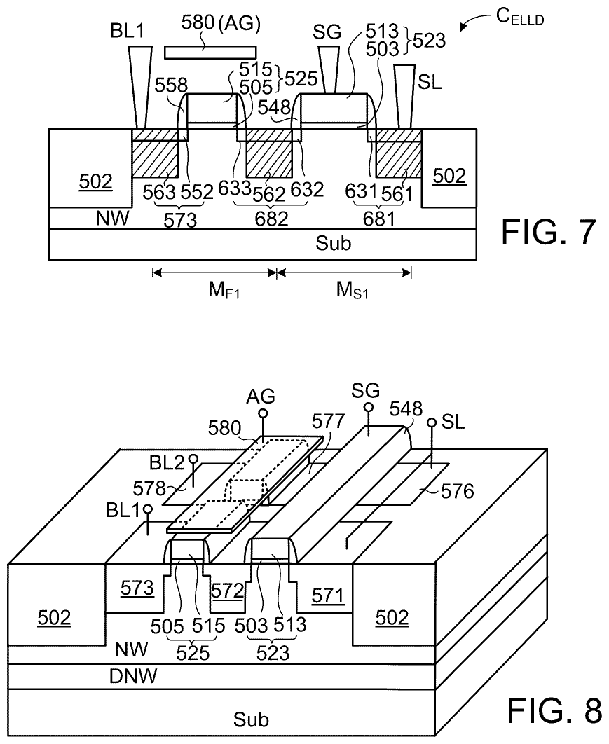

FIG. 7 is a schematic cross-sectional view illustrating the structure of a memory cell according to a fourth embodiment of the present invention. In comparison with the memory cell C_{ELL1} of the first embodiment, the structures of the merged p-doped regions 681, 682 and 573 are distinguished. For brevity, only the difference between the two memory cells C_{ELL1} and C_{ELLD} will be described as follows.

As shown in FIG. 7, the p-LDD region 631 and the p-type ion implantation regions 561 are collaboratively formed as the merged p-doped region 681. The merged p-doped region 681 is formed under the surface of the semiconductor substrate Sub and located beside a first side of the gate structure 523. A p-LDD region 632, a p-LDD region 633 and the p-type ion implantation regions 562 are collaboratively formed as the merged p-doped region 682. The merged p-doped region 682 is formed under the surface of the semiconductor substrate Sub and arranged between the second side of the gate structure 523 and the first side of the gate structure 525. The p-LDD region 552 and the p-type ion implantation regions 563 are collaboratively formed as a merged p-doped region 573. The merged p-doped region 573 is formed under the surface of the semiconductor substrate Sub and located beside the second side of the gate structure 525.

In this embodiment, the p-LDD regions 631, 632, 633 and 552 are formed by using the LDD process of the LV production procedure. Consequently, the doping concentrations of the p-LDD regions 631, 632, 633 and 552 are equal. In addition, the doping depths of the p-LDD regions 631, 632, 633 and 552 are equal.

The equivalent circuits of the memory cells C_{ELLA}, C_{ELLB}, C_{ELLC} and C_{ELLD} in the second, third, fourth and fifth embodiments are identical to the equivalent circuit of the memory cell C_{ELL1} shown in FIG. 3J, and not redundantly described herein. Furthermore, when the program action, the erase action or the read action is performed, the bias voltages used in FIGS. 3K, 3L, 3M, 3N and 3O are feasible for the memory cells C_{ELLA}, C_{ELLB}, C_{ELLC} and C_{ELLD} in the second, third, fourth and fifth embodiments.

In the memory cell C_{ELL1} of the first embodiment, the channel width of the floating gate transistor M_{F1} and the channel width of the select transistor M_{S1} are identical. It is noted that numerous modifications may be made while retaining the teachings of the present invention. In some other embodiments, the channel width of the floating gate transistor M_{F1} and the channel width of the select transistor M_{S1} are different. For example, channel width of the floating gate transistor M_{F1} is smaller than the channel width of the select transistor M_{S1}.

FIG. 8 is a schematic cross-sectional view illustrating the structure of a memory cell according to a sixth embodiment of the present invention. In comparison with the memory cell of the first embodiment, a deep N-well (DNW) region is formed between the semiconductor substrate Sub and the N-well region NW. The bottom side of the deep N-well region DNW is contacted with the semiconductor substrate Sub. The top side of the deep N-well region DNW is contacted with the N-well region NW.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An erasable programmable non-volatile memory cell, comprising:
a first well region formed under a surface of a semiconductor substrate;
a first gate structure and a second gate structure formed on the first well region;
a first spacer formed on a sidewall of the first gate structure;
a second spacer formed on a sidewall of the second gate structure;
a first merged doped region, a second merged doped region and a third merged doped region formed in the first well region, wherein the first merged doped region is located beside a first side of the first gate structure, the second merged doped region is arranged between a second side of the first gate structure and a first side of the second gate structure, and the third merged doped region is located beside a second side of the second gate structure;
a metal layer formed over the second gate structure, wherein a vertical projection area of the metal layer covers the second gate structure;
a source line electrically connected with the first merged doped region;
a select gate line electrically connected with the first gate structure;
a bit line electrically connected with the third merged doped region;
an assist line connected with the metal layer; and
a plate capacitor, wherein a first terminal of the plate capacitor is electrically connected with the metal layer, and a second terminal of the plate capacitor is electrically connected with the second gate structure,
wherein the first merged doped region, the first gate structure and the second merged doped region are collaboratively formed as a select transistor, and the second merged doped region, the second gate structure and the third merged doped region are collaboratively formed as a floating gate transistor.

2. The erasable programmable non-volatile memory cell as claimed in claim 1, wherein a channel length of the floating gate transistor is smaller than a channel length of the select transistor.

3. The erasable programmable non-volatile memory cell as claimed in claim 2, wherein a channel width of the floating gate transistor is smaller than a channel width of the select transistor.

4. The erasable programmable non-volatile memory cell as claimed in claim 1, wherein the first gate structure includes a first gate dielectric layer and a first polysilicon gate layer, and the second gate structure includes a second gate dielectric layer and a second polysilicon gate layer, wherein the first gate dielectric layer and the second gate dielectric layer are in contact with the first well region, the first polysilicon gate layer is in contact with the first gate dielectric layer, and the second polysilicon gate layer is in contact with the second gate dielectric layer.

5. The erasable programmable non-volatile memory cell as claimed in claim 4, further comprising:
a block layer covering the second gate structure and the second spacer;
a first polysilicon layer formed on a top surface of the block layer; and
a conducting line electrically connected with the first polysilicon layer and the metal layer,
wherein the second polysilicon gate layer and the first polysilicon layer are collaboratively formed as the plate capacitor, and the plate capacitor is a polysilicon/polysilicon plate capacitor.

6. The erasable programmable non-volatile memory cell as claimed in claim 4, wherein the metal layer and the second polysilicon gate layer are collaboratively formed as the plate capacitor, and the plate capacitor is a metal/poly plate capacitor.

7. The erasable programmable non-volatile memory cell as claimed in claim 4, wherein when a program action is performed, the source line receives a program voltage, the select gate line receives a first on voltage, the bit line receives a ground voltage, and the assist line receives an assist voltage between the ground voltage and twice the program voltage, wherein when the program action is performed, a channel hot hole induced hot electron injection effect is generated, and electrons are attracted by the assist voltage and injected into the first polysilicon gate layer of the first gate structure.

8. The erasable programmable non-volatile memory cell as claimed in claim 4, wherein when an erase action is performed, the source line receives an erase voltage, the select gate line receives a second on voltage, the bit line receives a ground voltage, and the assist line receives an assist voltage lower than or equal to the ground voltage, wherein when the erase action is performed, a channel hot hole injection effect is generated, and holes are attracted by the assist voltage and injected into the first polysilicon gate layer of the first gate structure.

9. The erasable programmable non-volatile memory cell as claimed in claim 4, wherein when an erase action is performed, the source line receives an erase voltage, the select gate line receives an off voltage, the bit line receives a ground voltage, and the assist line receives an assist voltage lower than or equal to the ground voltage, wherein when the erase action is performed, a band to band hot hole injection effect is generated, and holes are attracted by the assist voltage and injected into the first polysilicon gate layer of the first gate structure.

10. The erasable programmable non-volatile memory cell as claimed in claim 4, wherein when a read action is performed, the source line receives a read voltage, the select gate line receives a ground voltage, and the bit line receives the ground voltage, and the assist line receives a voltage between the ground voltage and the read voltage, wherein when the read action is performed, a read current is generated between the source line and the bit line, and a storage state of the memory cell is determined according to a magnitude of the read current.

11. The erasable programmable non-volatile memory cell as claimed in claim 1, wherein the first merged doped region contains a first ion implantation region and a first lightly doped drain region, the second merged doped region contains a second ion implantation region, a second lightly doped drain region and a third lightly doped drain region, and the third merged doped region contains a third ion implantation region and a fourth lightly doped drain region, wherein the first lightly doped drain region is located beside the first side of the first gate structure and under the first spacer, the second lightly doped drain region is located beside the second side of the first gate structure and under the first spacer, the third lightly doped drain region is located beside the first side of the second gate structure and under the second spacer, and the fourth lightly doped drain region is located beside the second side of the second gate structure and under the second spacer.

12. The erasable programmable non-volatile memory cell as claimed in claim 11, wherein a first distance between the first lightly doped drain region and the second lightly doped drain region is greater than a second distance between the third lightly doped drain region and the fourth lightly doped drain region.

13. The erasable programmable non-volatile memory cell as claimed in claim 11, wherein the first lightly doped drain region, the second lightly doped drain region, the third lightly doped drain region and the fourth lightly doped drain region are formed by using a lightly doped drain process in a low voltage production procedure.

14. The erasable programmable non-volatile memory cell as claimed in claim 11, wherein a doping depth of the first lightly doped drain region and a doping depth of the second lightly doped drain region are equal, and a doping depth of the third lightly doped drain region and a doping depth of the fourth lightly doped drain region are equal, wherein the doping depth of the first lightly doped drain region is greater than the doping depth of the fourth lightly doped drain region.

15. The erasable programmable non-volatile memory cell as claimed in claim 14, wherein a doping concentration of the first lightly doped drain region and a doping concentration of the second lightly doped drain region are equal, and a doping concentration of the third lightly doped drain region and a doping concentration of the fourth lightly doped drain region are equal, wherein the doping concentration of the first lightly doped drain region is lower than the doping concentration of the fourth lightly doped drain region.

16. The erasable programmable non-volatile memory cell as claimed in claim 11, wherein a doping depth of the first lightly doped drain region and a doping depth of the second lightly doped drain region are equal, and the doping depth of the second lightly doped drain region and a doping depth of the third lightly doped drain region are equal, wherein the doping depth of the first lightly doped drain region is greater than the doping depth of the fourth lightly doped drain region.

17. The erasable programmable non-volatile memory cell as claimed in claim 16, wherein a doping concentration of the first lightly doped drain region and a doping concentration of the second lightly doped drain region are equal, and the doping concentration of the second lightly doped drain region and a doping concentration of the third lightly doped drain region are equal, wherein the doping concentration of the first lightly doped drain region is lower than the doping concentration of the fourth lightly doped drain region.

18. The erasable programmable non-volatile memory cell as claimed in claim 11, wherein a doping depth of the second lightly doped drain region and a doping depth of the third lightly doped drain region are equal, and the doping depth of the third lightly doped drain region and a doping depth of the fourth lightly doped drain region are equal, wherein a doping depth of the first lightly doped drain region is greater than the doping depth of the fourth lightly doped drain region.

19. The erasable programmable non-volatile memory cell as claimed in claim 18, wherein a doping concentration of the second lightly doped drain region and a doping concentration of the third lightly doped drain region are equal, and the doping concentration of the third lightly doped drain region and a doping concentration of the fourth lightly doped drain region are equal, wherein a doping concentration of the first lightly doped drain region is lower than the doping concentration of the fourth lightly doped drain region.

20. The erasable programmable non-volatile memory cell as claimed in claim 1, further comprising a deep well region, wherein a bottom side of the deep well region is in contact with the semiconductor substrate, and a top side of the deep well region is in contact with the first well region.
